(19) United States
(12) Patent Application Publication
(10) Pub. No.: US 2011/0278611 A1
(43) Pub. Date: Nov. 17, 2011

(54) LIGHT EMITTING DEVICE

(75) Inventors: Chun-Liang Lin, Taipei County (TW); Chung-Chun Lee, Yunlin County (TW); Chieh-Wei Chen, Taichung County (TW)

(73) Assignee: AU OPTRONICS CORPORATION, Hsinchu (TW)

(21) Appl. No.: 12/838,507

(22) Filed: Jul. 19, 2010

(30) Foreign Application Priority Data
May 17, 2010 (TW) 99115693

(51) Int. Cl. H01L 33/58

(52) U.S. Cl. 257/98; 257/E33.074

(57) ABSTRACT

A light emitting device includes a substrate and an organic electroluminescent device. Inside the substrate, there are a plurality of micro-structures proceeded with fusing and then curing. The organic electroluminescent device is disposed on the substrate.

### CROSS-REFERENCE TO RELATED APPLICATION

This application claims the priority benefit of Taiwan application serial no. 99115693, filed on May 17, 2010. The entirety of the above-mentioned patent application is hereby incorporated by reference herein and made a part of specification.

### BACKGROUND OF THE INVENTION

1. Field of the Invention

The present invention generally relates to a light emitting device, and more particularly, to a light emitting device with increased light emitting volume.

2. Description of Related Art

The electroluminescent device is a semiconductor device able to convert electrical energy into optical energy with high conversion efficiency, and it is commonly used in light emitting devices such as indicator, display panel and optical read-and-write head. Since the electroluminescent device is advantageous in no limitation of viewing angle, process simplicity, low cost, high response speed, broad application temperature range and full-color display so that it meets the requirement of the display performance in the multimedia age and is expected to play a major role in the mainstream display market.

Usually, an electroluminescent device includes an anode, a light-emitting layer and a cathode. The principle the electroluminescent device is based on is that injecting holes and electrons into an electroluminescent layer respectively through the anode and the cathode, and when the electrons encounter the holes in the electroluminescent layer they are recombined to form photons so as to emit light.

Since the electroluminescent layer and the transparent conductive layer serving as an electrode have high refractive index so that when the electrons and the holes are recombined, a part of the produced light would form an incident light with a large angle due to the refraction. As a result, a total internal reflection (TIR) is produced at the interface between the transparent conductive layer and the substrate or at the interface between the substrate and the air. The TIR makes the light unable to get out and thereby makes the light emitting volume insufficient to meet the application need.

### SUMMARY OF THE INVENTION

Accordingly, the present invention is directed to a light emitting device with higher light emitting volume.

The present invention is also directed to a light emitting device able to reduce TIR in the device.

The present invention is further directed to a light emitting device able to reduce the light total internally reflected by the substrate.

The present invention provides a light emitting device, which includes a substrate and an organic electroluminescent device (OELD). Inside the substrate, there are a plurality of micro-structures proceeded with fusing and then curing, and the OELD is disposed on the substrate.

According to the light emitting device described by an embodiment of the present invention, the above-mentioned micro-structures proceeded with fusing and then curing have a refractive index different from the refractive index of the substrate.

According to the light emitting device described by an embodiment of the present invention, the above-mentioned micro-structures proceeded with fusing and then curing are, for example, evenly distributed inside the substrate.

According to the light emitting device described by an embodiment of the present invention, the above-mentioned micro-structures proceeded with fusing and then curing are, for example, randomly distributed inside the substrate.

According to the light emitting device described by an embodiment of the present invention, the size of the above-mentioned micro-structures proceeded with fusing and then curing ranges between 0.1 μm and 60 μm.

According to the light emitting device described by an embodiment of the present invention, the above-mentioned micro-structures proceeded with fusing and then curing are formed, for example, with laser carving process.

According to the light emitting device described by an embodiment of the present invention, the above-mentioned micro-structures proceeded with fusing and then curing, for example, are not in contact with the OELD.

According to the light emitting device described by an embodiment of the present invention, the above-mentioned OELD includes an anode layer, an organic functional layer and a cathode layer, wherein the anode layer is disposed on the substrate, the organic functional layer is disposed on the anode layer and the cathode layer is disposed on the organic functional layer.

According to the light emitting device described by an embodiment of the present invention, the above-mentioned organic functional layer includes a hole injecting layer (HIL), a hole transporting layer (HTL), a light emitting layer (EML) and an electron injection layer (EIL). The HIL is disposed on the anode layer, the HTL is disposed on the HIL, the EML is disposed on the HTL and the EIL is disposed between the EML and the cathode layer.

According to the light emitting device described by an embodiment of the present invention, the above-mentioned OELD includes, for example, a plurality of organic electroluminescent units arranged in array.

The present invention also provides a light emitting device, which includes a substrate and an OELD. Inside the substrate, there are a plurality of micro-bubbles. The OELD is disposed on the substrate.

According to the light emitting device described by an embodiment of the present invention, the above-mentioned micro-bubbles have a refractive index different from the refractive index of the substrate.

According to the light emitting device described by an embodiment of the present invention, the above-mentioned micro-bubbles are, for example, evenly distributed inside the substrate.

According to the light emitting device described by an embodiment of the present invention, the above-mentioned micro-bubbles are, for example, randomly distributed inside the substrate.

According to the light emitting device described by an embodiment of the present invention, the size of the above-mentioned micro-bubbles ranges between 0.1 μm and 60 μm.

According to the light emitting device described by an embodiment of the present invention, the above-mentioned micro-bubbles, for example, are not in contact with the OELD.

According to the light emitting device described by an embodiment of the present invention, the light emitting device further includes a plurality of foaming particles doped inside the substrate, wherein the micro-bubbles are produced by the foaming particles.

According to the light emitting device described by an embodiment of the present invention, the material of the above-mentioned foaming particles is, for example, calcium carbonate, barium carbonate, sodium hydrogen carbonate and sodium carbonate.

The present invention further provides a light emitting device, which includes a substrate, a plurality of light scattering particles and an OELD. The light scattering particles are distributed inside the substrate and the OELD is disposed on the substrate.

According to the light emitting device described by an embodiment of the present invention, the above-mentioned light scattering particles have a refractive index different from the refractive index of the substrate.

According to the light emitting device described by an embodiment of the present invention, the above-mentioned light scattering particles are, for example, evenly distributed inside the substrate.

According to the light emitting device described by an embodiment of the present invention, the above-mentioned light scattering particles are, for example, randomly distributed inside the substrate.

According to the light emitting device described by an embodiment of the present invention, the size of the above-mentioned light scattering particles ranges between 0.1 μm and 60 μm.

According to the light emitting device described by an embodiment of the present invention, the above-mentioned light scattering particles, for example, are not in contact with the OELD.

Based on the depiction above, since inside the substrate in the light emitting device of the present invention there are micro-structures, micro-bubbles or light scattering particles, so that the light emitted from the OELD can produce scattering when entering the substrate and the scattered light can pass out of the substrate in various different angles, which reduces the TIR chance so as to increase the light emitting volume.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a sectional diagram of a light emitting device according to an embodiment of the present invention.

FIG. 2 is a sectional diagram of a light emitting device according to another embodiment of the present invention.

FIG. 3 is a sectional diagram of a light emitting device according to yet another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

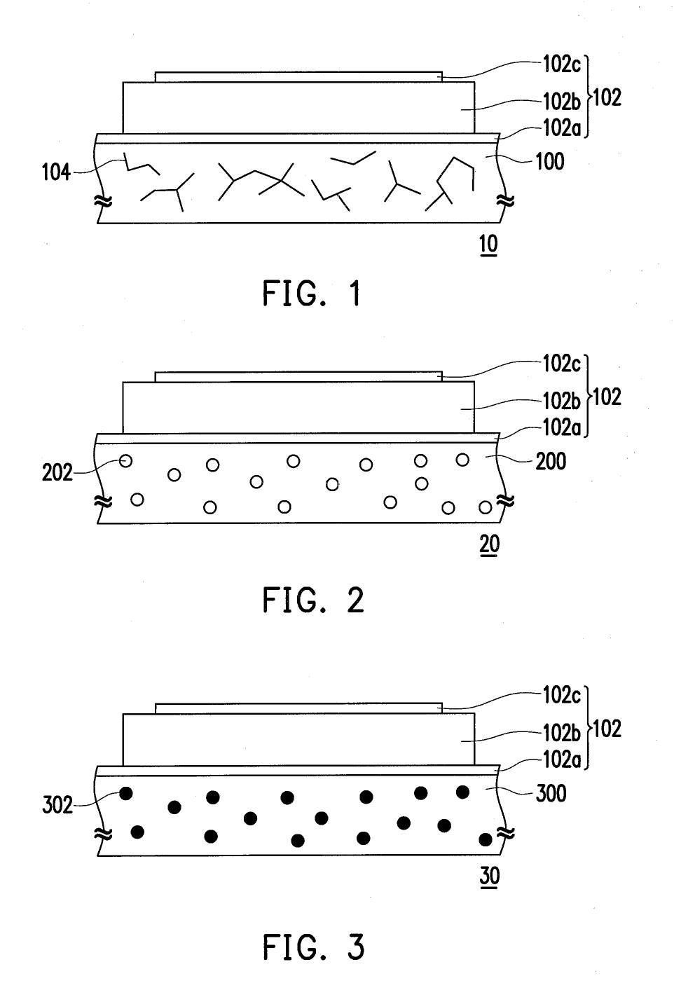

FIG. 1 is a sectional diagram of a light emitting device according to an embodiment of the present invention. Referring to FIG. 1, a light emitting device 10 includes a substrate 100 and an OELD 102. The substrate 100 is, for example, a glass substrate. Inside the substrate 100, there are a plurality of micro-structures 104 proceeded with fusing and then curing. The size of the micro-structures 104 ranges, for example, between 0.1 μm and 60 μm. In the embodiment, the micro-structures 104 are evenly distributed inside the substrate 100. In another embodiment, the micro-structures 104 can be also randomly distributed inside the substrate 100. The micro-structures 104 are formed with, for example, laser carving process, i.e., a laser light is in a single turn or in multiple turns focused inside the substrate 100 so that the structure of the substrate 100 is changed through laser light heating. The laser carving process can also control the depth of the micro-structures 104 formed inside the substrate 100 so that the micro-structures 104 are completely formed inside the substrate 100 and the substrate 100 keeps a flat surface as well. The refractive index of the formed micro-structures 104 can be different from the refractive index of the substrate 100.

The OELD 102 is disposed on the substrate 100. The OELD 102 is, for example, a plurality of organic electroluminescent units arranged in array. The OELD 102, for example, is not in contact with the micro-structures 104, or a part of the micro-structures 104 is in contact with the OELD 102. A buffer layer (not shown) can be further disposed between the substrate 100 and the OELD 102 so as to isolate the OELD 102 from contacting the micro-structures 104 of the surface of the substrate 100. The OELD 102 includes an anode layer 102a, an organic functional layer 102b and a cathode layer 102c. The anode layer 102a is disposed on the substrate 100, the organic functional layer 102b is disposed on the anode layer 102a and the cathode layer 102c is disposed on the organic functional layer 102b. The material of the anode layer 102a is, for example, transparent conductive oxide (TCO) such as indium tin oxide (ITO), Al doped ZnO (AZO), indium zinc oxide (IZO) or other transparent conduction materials, which the present invention is not limited to. The organic functional layer 102b comprises a hole injecting layer (HIL), a hole transporting layer (HTL), a light emitting layer (EML) and an electron injection layer (EIL). In order to clearly describe the embodiment, the HIL, the HTL, the EML and the EIL are not shown in FIG. 1. The HIL is disposed on the anode layer 102a, the HTL is disposed on the HIL, the EML is disposed on the HTL, and the EIL is disposed between the EML and the cathode layer 102c. In addition, the organic functional layer 102b further includes an electron transport layer (ETL) and a hole blocking layer (HBL), wherein the ETL is disposed between the EML and the HIL and the HBL is disposed between the HIL and the cathode layer 102c. The above-mentioned HIL, HTL, EML, ETL, EIL and HBL are well known by anyone skilled in the art so that the further descriptions are omitted. The material of the cathode layer 102c is, for example, metal, which the present invention is not limited to.

When the light produced by the OELD 102 enters the substrate 100, since the refractive index of the micro-structures 104 is different from the refractive index of the substrate 100, the light after encountering the micro-structures 104 would be scattered, which reduces the chance for the light travelling in the substrate 100 to produce TIR and thereby it makes the light able to get out of the substrate 100 in various different angles and increases the light emitting volume of the light emitting device 10.

It should be noted that the light emitting device 10 in the embodiment can be used in various illumination applications and color displays, preferred in illumination equipments and displays.

FIG. 2 is a sectional diagram of a light emitting device according to another embodiment of the present invention. Referring to FIG. 2, a light emitting device 20 includes a substrate 200 and an OELD 102. The OELD 102 is disposed on the substrate 200. The depiction related to the OELD 102 can refer FIG. 1, which is omitted to describe. The substrate 200 is, for example, a transparent plastic substrate. Inside the substrate 200, there are a plurality of micro-bubbles 202. The size of the micro-bubbles 202 ranges, for example, between 0.1 μm and 60 μm. In the embodiment, the micro-bubbles 202 are evenly distributed inside the substrate 200. In another embodiment, the micro-bubbles 202 are randomly distributed inside the substrate 200. The refractive index of the micro-bubbles 202 is different from the refractive index of the substrate 200. In addition, the micro-bubbles 202 are not in contact with the OELD 102, or a part of the micro-bubbles 202 is in contact with the OELD 102. A buffer layer (not shown) can be further included between the substrate 200 and the OELD 102 so as to isolate the OELD 102 from contacting the micro-bubbles 202 of the surface of the substrate 200.

The micro-bubbles 202 are produced, for example, by a plurality of foaming particles. In more details, during forming the substrate 200, in the plastic material, dopes foaming particles (for example, calcium carbonate, barium carbonate, sodium hydrogen carbonate and sodium carbonate) which are conducted to release gas after heating. After that, the foaming particles are evenly or randomly distributed inside the plastic material. Further, the plastic material is fused and moulded to form the substrate 200 which has a flat surface but contains micro-bubbles 202 therein or contains a part of micro-bubbles 202 on the surface of the substrate 200. Therefore, in another embodiment, inside the substrate 200, there may be foaming particles.

When the light produced by the OELD 102 enters the substrate 200, since the refractive index of the micro-bubbles 202 is different from the refractive index of the substrate 200, the light after encountering the micro-bubbles 202 would be scattered, which reduces the chance for the light travelling in the substrate 200 to produce TIR and thereby it makes the light able to get out of the substrate 200 in various different angles and increases the light emitting volume of the light emitting device 20.

It should be noted that the light emitting device 20 in the embodiment can be used in various illumination applications and color displays, preferred in illumination equipments and displays.

FIG. 3 is a sectional diagram of a light emitting device according to yet another embodiment of the present invention. Referring to FIG. 3, a light emitting device 30 includes a substrate 300, a plurality of light scattering particles 302 and an OELD 102. The OELD 102 is disposed on the substrate 300. The depiction related to the OELD 102 can refer FIG. 1, which is omitted to describe. The substrate 300 is, for example, an opal glass substrate or an alabaster glass substrate. The light scattering particles 302 are distributed inside the substrate 300. The size of the light scattering particles 302 ranges, for example, between 0.1 μm and 60 μm. In the embodiment, the light scattering particles 302 are evenly distributed inside the substrate 300. In another embodiment, the light scattering particles 302 are randomly distributed inside the substrate 300. The refractive index of the light scattering particles 302 is different from the refractive index of the substrate 300. In addition, the light scattering particles 302 are not in contact with the OELD 102, or a part of the light scattering particles 302 is in contact with the OELD 102. A buffer layer (not shown) can be further included between the substrate 300 and the OELD 102 so as to isolate the OELD 102 from contacting the m light scattering particles 302 of the surface of the substrate 300.

In more details, when the substrate 300 is an opal glass substrate, the inclusion (i.e., the light scattering particles 302) can be NaF or CaF₂, ZnS, Ca₃(PO₄)₂, SnO₂, As₂O₅, ZrO₂, TiO₂, etc; when the substrate 300 is an alabaster glass substrate, the particles of the inclusion have a larger size and the particles can be NaCl, Na₂SO₄, etc.

When the light produced by the OELD 102 enters the substrate 300, since the refractive index of the light scattering particles 302 is different from the refractive index of the substrate 300, the light after encountering the light scattering particles 302 would be scattered, which reduces the chance for the light travelling in the substrate 300 to produce TIR and thereby it makes the light able to get out of the substrate 300 in various different angles and increases the light emitting volume of the light emitting device 30.

It should be noted that the light emitting device 30 in the embodiment can be used in various illumination applications and color displays, preferred in illumination equipments and displays.

In summary, since inside the substrate in the light emitting device of the present invention there are micro-structures, micro-bubbles or light scattering particles, so that the light emitted from the OELD can produce scattering which reduces the TIR chance of the light inside the substrate and makes the light able to pass out of the substrate in various different angles so as to increase the light emitting volume of the light emitting device.

It will be apparent to those skilled in the art that the descriptions above are several preferred embodiments of the present invention only, which does not limit the implementing range of the present invention. Various modifications and variations can be made to the structure of the present invention without departing from the scope or spirit of the invention.

What is claimed is:

1. A light emitting device, comprising:
a substrate, wherein inside the substrate, there are a plurality of micro-structures proceeded with fusing and then curing; and
an organic electroluminescent device disposed on the substrate.

2. The light emitting device as claimed in claim 1, wherein the micro-structures proceeded with fusing and then curing have a refractive index different from a refractive index of the substrate.

3. The light emitting device as claimed in claim 1, wherein the micro-structures proceeded with fusing and then curing are evenly distributed inside the substrate.

4. The light emitting device as claimed in claim 1, wherein the micro-structures proceeded with fusing and then curing are randomly distributed inside the substrate.

5. The light emitting device as claimed in claim 1, wherein the size of the micro-structures proceeded with fusing and then curing ranges between 0.1 μm and 60 μm.

6. The light emitting device as claimed in claim 1, wherein the micro-structures proceeded with fusing and then curing are formed with laser carving process.

7. The light emitting device as claimed in claim 1, wherein the micro-structures proceeded with fusing and then curing are not in contact with the organic electroluminescent device.

8. The light emitting device as claimed in claim 1, wherein the organic electroluminescent device comprises:
an anode layer, disposed on the substrate;
an organic functional layer, disposed on the anode layer; and
a cathode layer, disposed on the organic functional layer.

9. The light emitting device as claimed in claim 8, wherein the organic functional layer comprises:
a hole injecting layer, disposed on the anode layer;
a hole transporting layer, disposed on the hole injecting layer;
a light emitting layer, disposed on the hole transporting layer; and
an electron injection layer, disposed between the light emitting layer and the cathode layer.

10. The light emitting device as claimed in claim 1, wherein the organic electroluminescent device comprises a plurality of organic electroluminescent units arranged in array.

11. A light emitting device, comprising:
a substrate, wherein inside the substrate, there are a plurality of micro-bubbles; and
an organic electroluminescent device disposed on the substrate.

12. The light emitting device as claimed in claim 11, wherein the micro-bubbles have a refractive index different from the refractive index of the substrate.

13. The light emitting device as claimed in claim 11, wherein the micro-bubbles are evenly distributed inside the substrate.

14. The light emitting device as claimed in claim 11, wherein the micro-bubbles are randomly distributed inside the substrate.

15. The light emitting device as claimed in claim 11, wherein the size of the micro-bubbles ranges between 0.1 μm and 60 μm.

16. The light emitting device as claimed in claim 11, wherein the micro-bubbles are not in contact with the organic electroluminescent device.

17. The light emitting device as claimed in claim 11, wherein the organic electroluminescent device comprises:
an anode layer, disposed on the substrate;
an organic functional layer, disposed on the anode layer; and
a cathode layer, disposed on the organic functional layer.

18. The light emitting device as claimed in claim 17, wherein the organic functional layer comprises:
a hole injecting layer, disposed on the anode layer;
a hole transporting layer, disposed on the hole injecting layer;
a light emitting layer, disposed on the hole transporting layer; and
an electron injection layer, disposed between the light emitting layer and the cathode layer.

19. The light emitting device as claimed in claim 11, wherein the organic electroluminescent device comprises a plurality of organic electroluminescent units arranged in array.

20. The light emitting device as claimed in claim 11, wherein the light emitting device further comprises a plurality of foaming particles doped inside the substrate, wherein the micro-bubbles are produced by the foaming particles.

21. The light emitting device as claimed in claim 11, wherein the material of the foaming particles comprises calcium carbonate, barium carbonate, sodium hydrogen carbonate and sodium carbonate.

22. A light emitting device, comprising:
a substrate;
a plurality of light scattering particles distributed inside the substrate; and
an organic electroluminescent device disposed on the substrate.

23. The light emitting device as claimed in claim 22, wherein the light scattering particles have a refractive index different from the refractive index of the substrate.

24. The light emitting device as claimed in claim 22, wherein the light scattering particles are evenly distributed inside the substrate.

25. The light emitting device as claimed in claim 22, wherein the light scattering particles are randomly distributed inside the substrate.

26. The light emitting device as claimed in claim 22, wherein the size of the light scattering particles ranges between 0.1 μm and 60 μm.

27. The light emitting device as claimed in claim 22, wherein the light scattering particles are not in contact with the organic electroluminescent device.

28. The light emitting device as claimed in claim 22, wherein the organic electroluminescent device comprises:
an anode layer, disposed on the substrate;
an organic functional layer, disposed on the anode layer; and
a cathode layer, disposed on the organic functional layer.

29. The light emitting device as claimed in claim 28, wherein the organic functional layer comprises:
a hole injecting layer, disposed on the anode layer;
a hole transporting layer, disposed on the hole injecting layer;
a light emitting layer, disposed on the hole transporting layer; and
an electron injection layer, disposed between the light emitting layer and the cathode layer.

30. The light emitting device as claimed in claim 22, wherein the organic electroluminescent device comprises a plurality of organic electroluminescent units arranged in array.
